(19) United States
(12) Patent Application Publication
(10) Pub. No.: US 2006/0091949 A1
(43) Pub. Date: May 4, 2006

(54) Signal correction by predistortion

(76) Inventor: Antony James Smithson, North Yorkshire (GB)

Correspondence Address: MENDELSOHN AND ASSOCIATES, P.C., 1500 JOHN F. KENNEDY BLVD., SUTIE 405, PHILADELPHIA, PA, 19102, US

(21) Appl. No.: 10/515,201

(22) PCT Filed: May 22, 2003
(86) PCT No.: PCT/GB03/02242

§ 371 Date: Aug. 19, 2005

(30) Foreign Application Priority Data
May 24, 2002 (GB) 02012023.6

(51) Int. Cl. H03F 1/26

(52) U.S. Cl. 330/149

(57) ABSTRACT

A digital predistorter comprises a module (J) for producing a counteracting signal Vₘ₁ for combination with the input signal of a power amplifier to correct the output of the amplifier for distorting memory effects within the amplifier. The module (J) produces the counteracting signal Vₘ₁ by convolving (see FIG. 6) non-linear functions of the input signal with impulse response characteristics related to the memory effects being corrected.

The present invention relates to apparatus for, and methods of, predistorting an input signal to an item of signal handling equipment, such as a power amplifier in a mobile radio telephone, in order to reduce the amount of distortion that the equipment causes in the output signal produced in response to the input signal.

It is known to perform predistortion of power amplifier input signals in the digital domain. The digital predistorter is finding increased usage in linearising RF power amplifiers and this is partly due to the recent availability of high sampling rate Analogue to Digital converters (ADCs) and Digital to Analogue converters (DACs) and corresponding improvements in the speed of Digital Signal Processing (DSP) hardware which make this form of linearisation possible. It is also due to the increasing use of non-constant envelope modulation schemes and the ever important need to increase amplifier efficiency which makes this form of linearisation desirable.

However, most conventional predistorters only correct for amplifier distortion that is a function of the instantaneous signal amplitude. This is commonly referred to as AM (Amplitude Modulation) to AM and AM to PM (Phase Modulation) distortion. This form of predistorter, when implemented digitally, often operates with two look-up tables (for adjusting, for example, the gain and phase of the amplifier input signal) which are indexed by the signal amplitude (or some function of the input amplitude) and which then act to modify the amplitude and phase of the signal applied to the amplifier input so as to counter its distortion.

Unfortunately many real amplifiers exhibit distortion that is a function of the signal in the past as well as the present. These amplifiers are said to possess memory. The AM-AM and AM-PM type predistorter described above will have limited performance when linearising an amplifier that exhibits memory since it can only correct for that component of the distortion which can be expressed as a function of the instantaneous signal amplitude.

In general, the amplifier memory effect will become more significant as the signal bandwidth increases and the conventional AM-AM and AM-PM predistorter performance will therefore get correspondingly worse. Since there is often a tendency for signal bandwidth to increase (particularly in the area of mobile telecommunications) the problem of memory effect distortion, and its correction, is now becoming a major problem for RF power amplifier design.

One aim of the invention is to provide a predistortion technique that can correct for memory effect distortion in equipment such as RF power amplifiers.

According to one aspect, the invention provides apparatus for linearising an output signal produced by signal handling equipment by producing a counteracting signal for combination with an input signal to said equipment to counteract memory-effect distortion in said output signal, the apparatus comprising processing means for creating a correction signal by way of convolving a first function of the input signal with a first impulse response characteristic and subtracting means for subtracting from said correction signal the expectation value of said correction signal at the current state of said input signal in order to produce a difference signal that is used to create said counteracting signal.

The invention also consists in a method of producing a counteracting signal for combination with an input signal to signal handling equipment for counteracting memory-effect distortion in an output signal of said equipment, the method comprising creating a correction signal by way of convolving a first function of said input signal with a first impulse response characteristic and the method further comprising subtracting from said correction signal the expectation value of said correction signal at the current state of said input signal in order to produce a difference signal that is use to create said counteracting signal.

The predistortion technique according to the invention may provide significant improvements in amplifier linearity by allowing the memory effect distortion component to be corrected alongside the instantaneous distortion component.

The predistortion technique according to the invention may allow predistortion correction to be provided over a wider bandwidth than without memory correction, for typical high-power RF devices. This is due to the fact that memory effects tend to become increasingly dominant with increasing bandwidth.

The correction signal produced by the invention can be used in conjunction with an additional correction signal which has been produced by an “instantaneous amplitude” predistortion technique so that correction of the signal handling equipment for instantaneous and memory effects can be performed. Such a predistorter architecture would correct for the instantaneous AM-AM and AM-PM component of the distortion and also correct the component of distortion due to amplifier memory. One advantage of this scheme is that these two aspects of the predistorter can remain independent of one another such that a change to one aspect does not affect the other.

In one embodiment, in the creation of the correction signal, each of a number of further impulse response characteristics is convolved with a function of said input signal. The functions of the input signal taking part in each of the convolutions need not be the same.

In one embodiment, the process of generating the correction signal involves generating a function of a convolved signal (produced by convolving an impulse response characteristic with the input signal). Where several convolved signals are produced, a respective function of each convolved signal can be produced or the convolved signals could be combined and a signal then produced that is a function of the combined convolved signals. Of course, other ways of combining the convolved signal can be envisaged, such that a signal is produced that is some function of the convolved signals.

In one embodiment, an impulse response characteristic used in one or more convolutions has the form of an exponential decay.

In one embodiment, a function of the input signal used in one or more convolutions is a non-linear function of said input signal. The non-linear signal can be, for example, the square of, or the current of, the input signal.

In one embodiment, the difference signal is used to modulate a polar parameter (amplitude or phase) of said input signal in the production of the counteracting signal. In a preferred embodiment, two difference signals are produced, one for modulating the phase of, and the other for modulating the amplitude of, the input signal in the production of said counteracting signal.

In an alternative embodiment, the difference signal is used to modulate a Cartesian component of the input signal in the production of said counteracting signal. In a preferred embodiment, two difference signals are produced for modulating respective Cartesian components of the input signal in the production of said counteracting signal.

In preferred embodiments of the invention, the signal handling equipment upon which the linearising technique of the invention operates is a power amplifier or an arrangement of several of such.

By way of example only, certain embodiments of the invention will now be described with reference to the accompanying figures, in which:

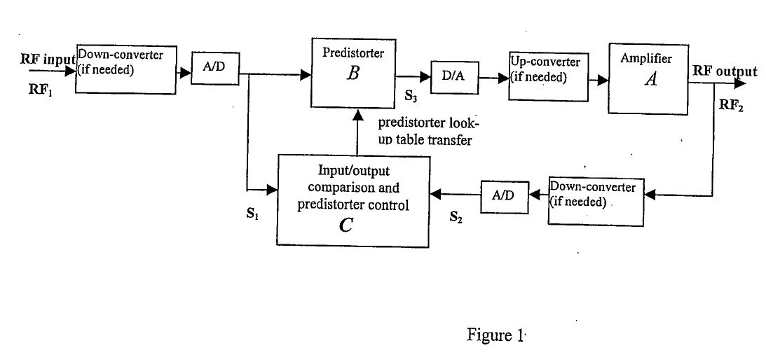

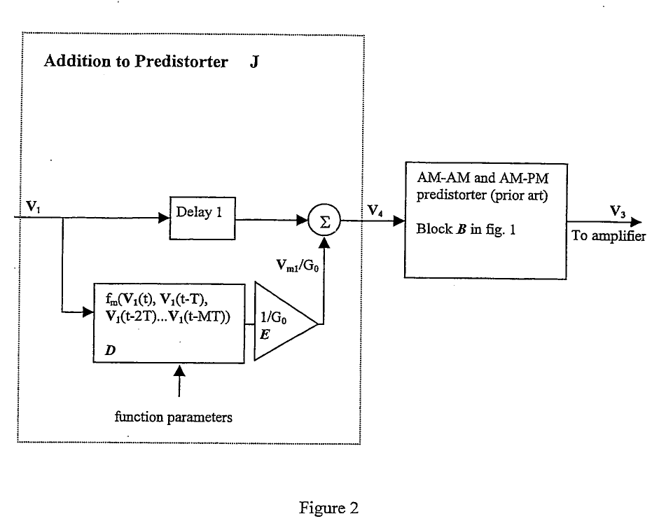

FIG. 1 is a block diagram showing the basic structure of a prior art predistorter;

FIG. 2 is a block diagram showing the basic structure of a predistorter according to an embodiment of the invention;

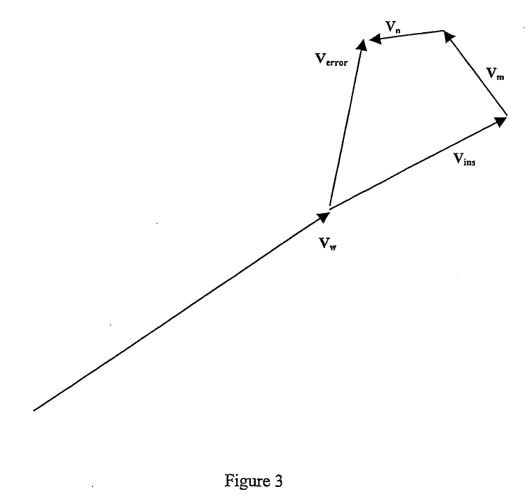

FIG. 3 is a vector diagram showing signals in an amplifier to be linearised;

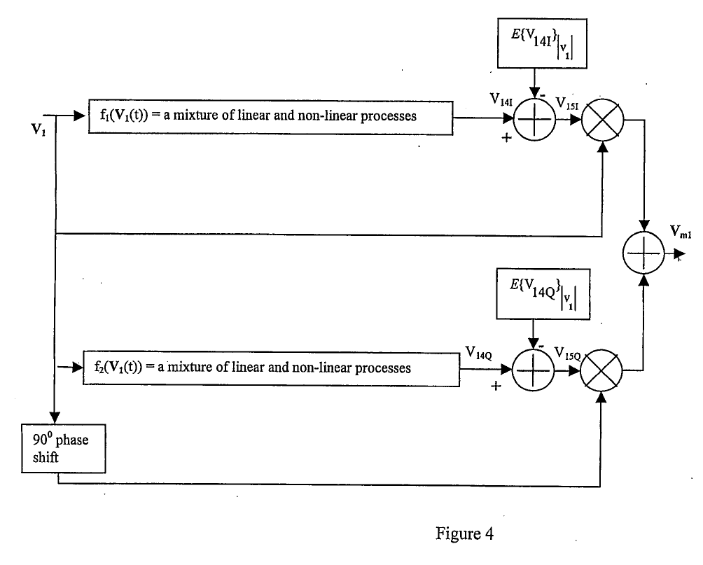

FIG. 4 is, a block diagram showing the structure of a Cartesian version of the predistorter of FIG. 2 in more detail;

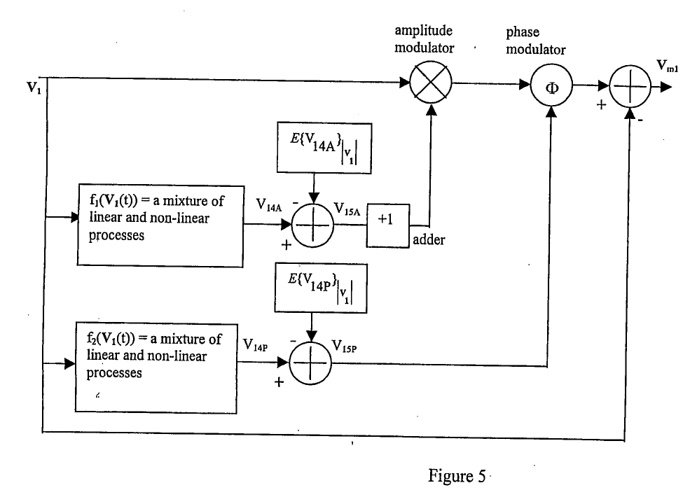

FIG. 5 is a block diagram showing the structure of a polar version of the predistorter of FIG. 2 in more detail;

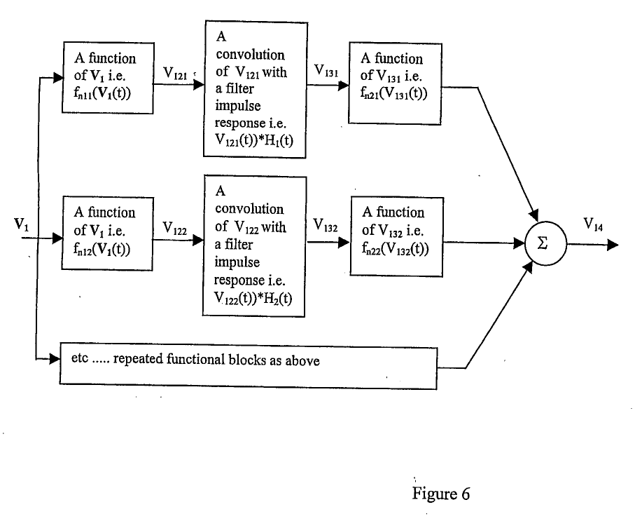

FIG. 6 is a block diagram showing the generic form of the functions f₁ and f₂ used in FIGS. 4 and 5;

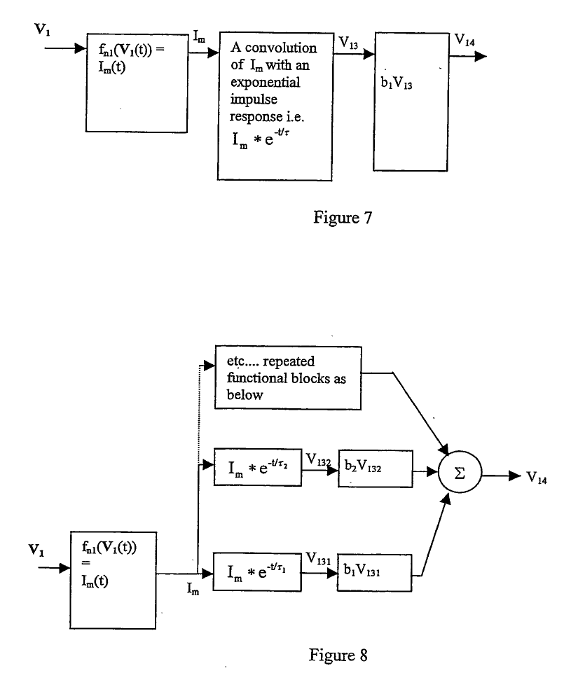

FIG. 7 shows a variant of the structure of the functions f₁ and f₂ given in FIG. 6; and

FIG. 8 shows another variant of the structure of the functions f₁ and f₂ given in FIG. 7.

The basic building blocks of a prior art digital predistorted amplifier are shown in FIG. 1. This form of predistorter often operates with two look-up tables (for adjusting, for example, the gain and phase of the amplifier input signal) which are indexed by the signal amplitude, or some function of the input amplitude, and which then act to modify the amplitude and phase of the signal applied to the amplifier input so as to counter its distortion. However, this form of predistorter will only correct for amplifier distortion which is a function of the instantaneous amplitude of the input signal. Such distortion is commonly referred to as AM (Amplitude Modulation) to AM and AM to PM (Phase Modulation) distortion and is referred to herein as instantaneous distortion.

Unfortunately, many real amplifiers exhibit distortion which is a function of the signal in the past as well as the present and these amplifiers are said to possess “memory”. The “instantaneous distortion” type predistorter known from the prior art described above will have limited performance when linearising an amplifier which exhibits this memory effect.

In FIG. 1, the RF input signal RF, to the amplifier A is, if necessary, down-converted in frequency and then converted into a digital signal S₁ at the A/D block. S₁ is supplied to a predistorter function B and also to control block C. The predistorter B alters S₁ into S₃ which subsequently undergoes conversion back to the analogue domain at the D/A block and, if necessary, frequency up-conversion before being supplied to the amplifier A. The linearised output RF₂ of amplifier A is then sampled by control block C as signal S₂ using appropriate A/D conversion and, if necessary, frequency down-conversion. Block C compares the signals S₁ and S₂ and uses the result to adapt the operation of predistorter B to optimise linearisation of RF₂.

FIG. 2 illustrates the basic architecture of the modified digital predistorter (B) which incorporates correction for both the instantaneous distortion signal and the memory distortion signal.

It can be seen that the modification to the predistorter which performs memory distortion correction involves a functional block J placed just prior to the AM-AM and AM-PM predistorter. In other words, there are no changes required to the AM-AM and AM-PM predistorter block. This provides the advantage that an existing predistorter product can be retrofitted in a relatively simple matter with a memory effect predistorter according to an embodiment of the present invention.

In block J, delay 1 compensates for delays in blocks D and E and T is the sample period and MT is the maximum time interval over which contribution to Vₘ (the output signal error component attributable to the memory effect) is non negligible.

If the predistorter is turned off (such that it acts as a linear gain stage), then the signal appearing at the output of the amplifier at any instant in time can be represented in phase and amplitude on a vector diagram as illustrated in FIG. 3.

The following vectors are shown in FIG. 3:

V_{w} is the linearly amplified output vector as would be output by an ideal, non distorting amplifier.

Vᵢₙₛ is the distortion vector which is simply a function of the instantaneous input signal amplitude (this represents AM to AM and AM to PM distortion). This will be called the instantaneous distortion vector.

Vₘ is the distortion vector which is a function of the input signal at times in the past as well as the present. This will be called the memory distortion vector.

Vₙ is an error vector due to system noise figure, digitising quantisation noise, gain and phase ripple, unwanted spurious signals etc. This error vector cannot be removed by predistortion and represents the residual distortion remaining after conventional predistortion and memory compensation have been applied.

Vₑᵣᵣₒᵣ is the total error vector taking into account all contributing error vectors.

|V₁| is the input signal amplitude, so we can write:
Vᵢₙₛ=fᵢₙₛ(|V₁|).

Also, Vₘ can be more precisely expressed as:
Vₘ=fₘ(V₁(t), V₁(t−δt), V₁(t−2δt) . . . V₁(t−M.δt))_{lim δt→0} (1)
where M.δt is the memory duration, i.e. the longest interval over which the contribution to Vₘ is non-negligible.

Vₘ has the property that its expectation value when evaluated at any input amplitude is zero. This can be expressed as
E{Vₘ}_{|V}_{₁}_{|}=0 (2)

The function E{V}_{|V}_{₁}_{|}is the expectation value or mean value of V when evaluated at some amplitude |V₁|.

The purpose of the predistorter is to distort the signal (or vector) at the amplifier input such that the signal at the amplifier output has an additional vector present which is equal and opposite to the total distortion vector produced by the amplifier. In this way the net distortion vector present at the amplifier output is zero (ideally).

Since the instantaneous distortion vector Vᵢₙₛ can be defined as a function of only the instantaneous input amplitude |V₁| i.e. Vᵢₙₛ=f(|V₁|) it follows that in order to predistort and remove this vector at the amplifier output we need a predistorter which is also a function of the instantaneous input amplitude. If V₁ at any instant of time is expressed as a complex quantity:
V₁=A₁exp(jθ₁) where A₁=|V₁|
then the predistorter output V₃ can be written
V₃=Gₚ(A₁).A₁exp(jθ₁+jPₚ(A₁)) (3)
where Gₚ(A₁) and Pₚ(A₁) represent the amplitude dependent gain and phase shift of the predistorter.

If we also represent the amplifier amplitude dependent gain and phase shift as G_{A}(A₁) and P_{A}(A₁) then the predistortion is optimum for the instantaneous distortion vector (Vᵢₙₛ=0) when the amplifier output can be written as
V₂=G_{A}(Gₚ(A₁).A₁).Gₚ(A₁).A₁.exp(jθ₁+jPₚ(A₁)+jP_{A}(Gₚ(A₁).A₁)) (4)
where:
G_{A}(Gₚ(A₁).A₁).Gₚ(A₁)=G₀=constant (5)
and:
Pₚ(A₁)+P_{A}(Gₚ(A₁).A₁)=Θ₀=constant (=0 for simplicity) (6)

A common way of implementing the predistorter correction for Vᵢₙₛ is through the use of look-up tables for Gₚ(A₁) and Pₚ(A₁) and which satisfy equations 5 and 6. Alternatively, if the predistorter is implemented using Cartesian signals we use look-up tables LI(A₁) and LQ(A₁) such that
V₃={LI(A₁)+j.LQ(A₁)}.A₁.exp(jθ₁) (7)
and where Gₚ(A₁)={LI(A₁)²+LQ(A₁)²}^{1/2} (8)
Pₚ(A₁)=tan⁻¹(LQ(A₁)/LI(A₁)) (9)

Removing the memory distortion vector Vₘ from the amplifier output can be achieved by adding a signal vector Vₘ₁/G₀ to the predistorter input signal V₁. In this way the output of the amplifier when the predistorter look-up tables G_{P} and P_{P} (or LI and LQ) satisfy equations 5 and 6 is:
V₂=G₀.V₁+Vₘ₁+V′ₘ+Vₙ (10)
where V′ₘ is the memory distortion vector which is now slightly different from Vₘ owing to the predistortion of V₁. However, V′ₘ will still have the same form as equation 1 and will satisfy equation 2.

If Vₘ₁ is chosen such that Vₘ₁=−V′ₘ then we are left with
V₂=G₀.V₁+Vₙ (11)

In other words the amplifier non-linearity signals have been removed and we have at the amplifier output a linearly amplified input signal and noise.

The function to be evaluated in block D of FIG. 2 is therefore of the form:
fₘ(V₁(t), V₁(t−δt), V₁(t−2δt) . . . V₁(t−Mδt))_{lim δt→0}
and must satisfy the condition E{fₘ( )}_{|V}_{₁}_{|}=0.

The function fₘ( ) will, in general, be a mixture of linear and non-linear processes and some specific embodiments for this function are summarised below.

In general, the function fₘ( ), the function implemented by block D of FIG. 2, will be a mixture of linear and non-linear processes and its detailed implementation will vary according to the characteristics of the specific amplification device being used. In FIGS. 4 and 5, fₘ( ) is shown in a form that will facilitate implementation in an FPGA (Field Programmable Gate Array) or ASIC (Application Specific Integrated Circuit).

A generic Cartesian implementation of fₘ( ) is presented in FIG. 4 which is sufficiently general to cover the majority of amplification devices. The function E{V}_{|V}_{₁}_{|} is the expectation value or mean value of V when evaluated at the input amplitude |V₁|. Depending on the form of fₘ( ) it may be possible to express E{V_{14I}}_{|V}_{₁}_{|} and E{V_{14Q}}_{|V}_{₁}_{|} as relatively simple functions of V₁ for ease of calculation. E{V_{14I}}_{|V}_{₁}_{|} is subtracted from f₁ to produce a first difference signal and E{V_{14Q}}_{|V}_{₁}_{|} is subtracted from f₂ to produce a second difference signal. The subtraction of the quantities E{V_{14I}}_{|V}_{₁}_{|} and E{V_{14Q}}_{|V}_{₁}_{|} ensures that E{Vₘ}_{|V}_{₁}_{|}=0 or E{fₘ( )}_{|V}_{₁}_{|}=0 as required. The difference signal produced in the f₁ path is multiplied with the version of V₁ passing through block D. The difference signal produced in the f₂ path is multiplied with a version of V₁ that has been offset by 90 degrees. The outputs of the two multiplication processes are then summed to produce Vₘ₁.

A generic polar implementation of fₘ( ) is presented in FIG. 5 which is sufficiently general to cover the majority of amplification devices. The subtraction of E{V_{14A}}_{|V}_{₁}_{|} and E{V_{14P}}_{|V}_{₁}_{|} ensures that E{Vₘ}_{|V}_{₁}_{|}=0 or E{fₘ( )}_{|V}_{₁}_{|}=0 as required. The difference signal produced in the f₂ path is used to modulate the phase of the version of V₁ passing through block D. The difference signal produced in the f₁ path is offset by +1 and then used to modulate the amplitude of the version of V₁ passing through block D.

It should be noted that the calculations performed in FIGS. 4 and 5 can be carried out on with signals represented in real number format or in complex number format. To exemplify the latter, signal V₁ in FIG. 4 can be represented as a complex number having both real and imaginary components.

Clearly, if functional block J (FIG. 2) is modified by removing the direct path for V₁ then in this embodiment of fₘ( ) the subtraction of V₁ just prior to output of Vₘ₁ is unnecessary.

The nature of the functions f₁ and f₂ employed in FIGS. 4 and 5 will now be discussed in more detail with reference to FIGS. 6, 7 and 8.

FIG. 6 shows the general form used for both of the functions f₁ and f₂. V₁ is supplied to each of a number of paths where signal processing is performed. The outputs of the paths are then summed to produce signal V₁₄. There can be as many paths as required. Each path operates on V₁ to produce initially a signal, e.g. V₁₂₁, which is a function of V₁, which is then convolved with a filter impulse response, e.g. H₁(t), to produce a further signal, e.g. V₁₃₁, which is in turn processed such that a function, e.g. fₙ₂ₗ, of that signal issues from the path to the summation point. It will be apparent that f₁ need not be the same as f₂, for example fₙ₁₁ for f₁ and f₂ need not be the same.

The preferred generic embodiment of functions f₁ and f₂ can be significantly simplified if we make a number of assumptions relating to the physical cause of the amplifier memory effect. If we assume that the memory effect is due to modulation of the amplitude or phase of the signal and the modulation is linearly proportional to the value of a single physical variable (such as device temperature or bias voltage) and if we assume the physical variable is a function of the mean current (Iₘ) through the amplifying device and the function has an impulse response of the form e^{-t/τ}, then the form of f₁ and f₂ can be simplified to that shown in FIG. 7.

In many cases it is a good approximation to make Iₘ(t)≈|V₁(t)|² and it should be noted that in general the time constant τ and coefficient b₁ will be different for functions f₁ and f₂.

If we assume that the amplifier memory effect is due to modulation of the amplitude or phase of the signal and the modulation is linearly proportional to the value of several physical variables (such as device temperature, bias voltage etc.) and if we assume the physical variables are separate functions of the mean current (Iₘ) through the amplifying device and the functions have an impulse response of the form e^{-t/τ} then the form of fₘ( ) can be simplified to that shown in FIG. 8. It is assumed that the mean current is averaged over a time interval significantly longer than the carrier period and significantly shorter than the period of the maximum modulation signal frequency. Depending on the amplification device it may again be valid to approximate Iₘ(t) as |V₁(t)|².

In particular the situation postulated in the preceding paragraph can occur when the memory vector is made up from a number of memory effects at differing time-constants. This is likely to be the situation for most power amplifiers, as memory effects will result from thermal issues in the power device(s) and bias interaction with the range of de-coupling capacitors typically used on the gate and drain of, for example, an FET device. Each of these (the thermal and multiple capacitor-based time-constants) will result in a memory vector which has a different time constant.

1. Apparatus for linearising an output signal produced by signal handling equipment by producing a counteracting signal for combination with an input signal to said equipment to counteract memory-effect distortion in said output signal, the apparatus comprising processing means for creating a correction signal by way of convolving a first impulse response characteristic with a function of the input signal to produce a convolved signal and subtracting means for subtracting from said correction signal a mean value of said correction signal at the current state of said input signal in order to produce a difference signal that is used to create said counteracting signal.

2-12. (canceled)
